(19) United States
(12) Patent Application Publication
(10) Pub. No.: US 2005/0184603 A1
(43) Pub. Date: Aug. 25, 2005

(54) Thermotunnel converter with spacers between the electrodes

(76) Inventor: Artemi Markovich Martsinovsky, St. Petersburg (RU)

Correspondence Address: Borealls Technical Limited, 23545 NW Skyline Blvd, North Plains, OR, 97133-9204, US

(21) Appl. No.: 11/094,114

(22) Filed: Mar. 29, 2005

Related U.S. Application Data
(63) Continuation-in-part of application No. 10/232,436, filed on Aug. 28, 2002, now Pat. No. 6,876,123.
(60) Provisional application No. 60/315,537, filed on Aug. 28, 2001.

(51) Int. Cl. H02K 37/00; H01L 21/20; H02P 8/00

(52) U.S. Cl. 310/49 R; 318/696

(57) ABSTRACT

A thermotunneling converter is disclosed comprising a pair of electrodes having inner surfaces substantially facing one another, and a spacer or plurality of spacers positioned between the two electrodes, having a height substantially equal to the distance between the electrodes, and having a total cross-sectional area that is less than the cross-sectional area of either of the electrodes. In a preferred embodiment, a vacuum is introduced, and in a particularly preferred embodiment, gold that has been exposed to cesium vapor is used as one or both of the electrodes. In a further embodiment, the spacer is made of small particles disposed between the electrodes. In a yet further embodiment, a sandwich is made containing the electrodes with an unoxidized spacer. The sandwich is separated and the spacer is oxidized, which makes it grow to a required height whilst giving it insulatory properties, to allow for tunneling between the electrodes.

### CROSS-REFERENCE TO RELATED APPLICATIONS

This application is a continuation-in-part application of application Ser. No. 10/232,436 filed Aug. 28, 2002, and which claims the benefit of U.S. Provisional Application No. 60/315,537, filed Aug. 28, 2001.

### BACKGROUND OF THE INVENTION

The present invention relates to means for interconverting thermal energy and electric power, and more especially to thermotunneling devices for cooling and power generation.

In U.S. Pat. No. 3,169,200 to Huffman, a multilayer converter is described which comprises two electrodes, intermediate elements and oxide spacers disposed between each adjacent element. A thermal gradient is maintained across the device and opposite faces on each of the elements serve as emitter and collector. Electrons tunnel through each oxide barrier to a cooler collector, thereby generating a current flow through a load connected to the two electrodes.

A major drawback of this approach are the losses due to thermal conduction: although the oxide spacers have a small contact coefficient with the emitter and collector elements, which minimizes thermal conduction, the number of elements required for the operation of the device means that thermal conduction is not insignificant. In fact, in order for back heat flux from the hot side of the device to the cold side to sufficiently low for good efficiency, the temperature difference between adjacent layers should be of the order of 10⁻⁵ K.

This means that the device must contain some 10⁶ elements in order to provide reasonable efficiency, and this is difficult to manufacture.

There remains a need in the art therefore for a device having fewer elements, which is easier to fabricate, and in which losses due to thermal conduction are further reduced.

### BRIEF SUMMARY OF THE INVENTION

In broad terms, the present invention is a thermotunneling device, having a plurality of electrodes, each separated by a strip or other shaped spacer or plurality of spacers, enclosed in an airproof housing. The housing allows for a vacuum or inert gas to exist between the gaps in the spacer material, and is typically divided into two parts by electrical and thermal insulators. One part is connected to the first electrode and the other part is connected to the last electrodes via good electrical and thermal contacts. In preferred embodiments, the spacer materials are either thermal or electrical insulators, or are both.

The invention also provides a method for fabricating such a thermotunneling device in which various layers are built with insulating spacers between them, arranged as long strips running across each layer, which subsequent layers are balanced upon. In one embodiment, a sacrificial layer may be introduced in-between and around the spacers, and the subsequent conductive layer is deposited on both the spacer element and the sacrificial layer. In another embodiment, the invention provides the various layers to be thin sheets of metal. In this embodiment, the spacers may be formed of buckyballs, nanotubes (for example, of carbon or boron) or nanowires arranged between each sheet of metal and the adjacent one, to keep the sheets apart. In a yet further embodiment, the spacers comprise Al₂O₃, and are arranged as one or many columns between each pair of layers. Other embodiments, including different housing embodiments, are described below.

In a preferred embodiment, the device has approximately 100 layers, which corresponds to a temperature gradient between adjacent layers of the order of 0.1K. In a further preferred embodiment, the device has approximately 10 layers. In a further preferred embodiment, the device has a single layer.

A technical advantage of the present invention is that only a hundred or so layers may be used to achieve the thermotunneling effect with sufficient efficiency for commercial applications. This is more easily achievable than the prior art 10⁶ layers. In some embodiments, this number is reduced to about 10 layers, and even to just two electrodes.

Another technical advantage of the present invention is that adjacent electrodes may be spaced more than 40 angstroms apart, without requiring entire oxide films in between adjacent electrodes.

Another technical advantage of the present invention is that it may be constructed using micromachining or other methods.

An additional technical advantage of the present invention is that the basic design can be modularly increased or decreased in accordance with the intended usage of the device, by adding more, or reducing the number of layers.

An additional technical advantage of the present invention is that it results in high electrical output, over a range of temperature differentials, when the device is used as a generator.

A yet additional technical advantage of the present invention is that it allows thermotunneling devices to be made more cheaply, quickly, and easily.

Further objects and advantages of this invention will become apparent from a consideration of the figures and the ensuing descriptions.

### BRIEF DESCRIPTION OF THE SEVERAL VIEWS OF THE DRAWING

For a more complete explanation of the present invention and the technical advantages thereof, reference is now made to the following description and the accompanying drawings, in which:

FIGS. 1a-f illustrates how spacers may be deposited, the gap or gaps between them filled in, and subsequent electrodes deposited above the spacers;

FIGS. 2a-e illustrates how a removable layer may be laid upon an electrode, leaving gaps of appropriate sizing for the spacers, which are then added, a subsequent electrode laid above them, and the removable material removed;

FIGS. 3a-d illustrates how nanotubes may be arranged upon an electrode, and a subsequent electrode laid upon the carbon nanotubes;

FIGS. 4a-d illustrates how a potential spacer is deposited upon an electrode, and a second electrode laid upon that. The second electrode is distanced, and the potential spacer is grown to have the correct size and insulating properties;

FIGS. 5a-d illustrate arrangements of the replicated surfaces of adjacent electrodes with plurality spacers between them;

FIGS. 6a-b illustrates how plurality of the layers may be encapsulated into an airproof envelope and different embodiment of such envelope and insulator unit;

FIGS. 7 and 8a-b illustrate how a long spacer, embedded into the electrode body, may be created upon an electrode, and a second electrode laid upon that;

FIGS. 9a-b illustrates the replicate essence of electrode pairs of a thermotunnel converter;

FIGS. 10a-e illustrates the force balance between layers;

FIGS. 11a-e illustrates how complicated electrodes may be deposited.

### DETAILED DESCRIPTION OF THE INVENTION

The present invention is directed to a thermotunneling converter. Provided are two electrodes, separated from one another by a vacuum, and portions of spacer material. In one embodiment there consist a multiple of intermediate elements, acting as subsequent emitters and collectors, between the electrodes. Between each pair of layers there is a percentage of spacer material, and the remaining space is evacuated to less than a few Torr, or filled with an inert gas at a similar pressure, resulting in low thermal conductivity. Embodiments of the present invention include using columns, honeycombs, or strips, etc of insulating material in between each pair of layers as the spacers, to keep the layers apart whilst leaving room for a vacuum or gas backfill (at a few Torr) in between the conductive layers.

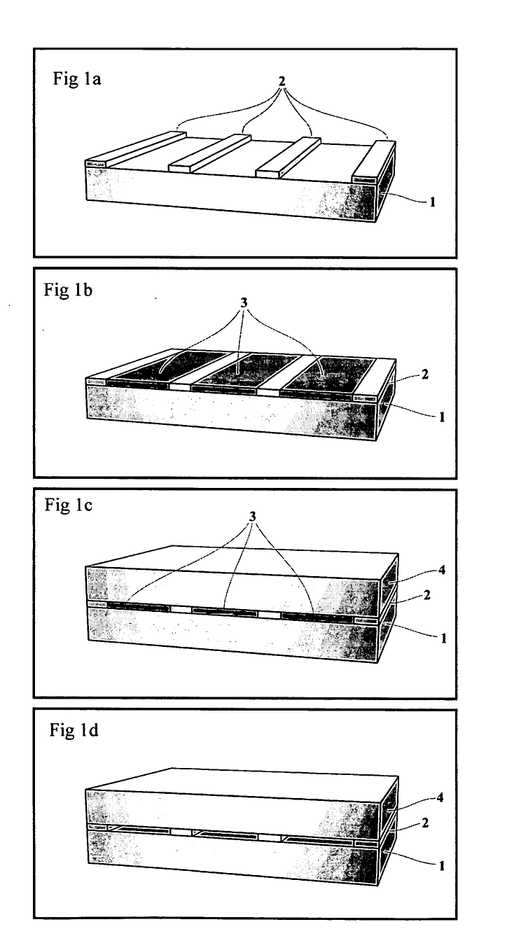

In a first embodiment, an electrode surface is prepared, and arranged upon it are a plurality of spacers. These may be deposited, applied through a mask and grown, gently laid down, or otherwise placed upon the electrode surface. The spaces between the spacers are then filled with a removable material, up to the height of the spacers. In one preferred embodiment, there is only one spacer, in the form of a large “X” stretching across the electrode surface. This allows for easier subsequent removal of the removable material. A second electrode is then laid down or deposited as a liquid and hardened, or otherwise placed upon the spacers and removable material. These steps are repeated with more layers of spacers and removable material, and subsequent electrodes, until the device has a required number of layers. The removable material is then dissolved, evaporated or otherwise removed. The removable material may be completely removed from the device, or allowed to remain at the base of a housing to the device where it will not interfere with the workings of the device. In one embodiment, a hole is drilled through the center of the device, through all the layers, and the removable material is removed through that. In a different embodiment, each layer of removable material is removed straight after the electrode above it has been placed in position. This approach may be better understood by reference to FIGS. 1a-f and Example 1. FIG. 1a illustrates how spacer material 2 may be laid upon a first electrode 1. In FIG. 1b, the gaps between the strips of spacer material 2 are subsequently filled with removable material 3. FIG. 1c shows how a second electrode 4 is deposited above the layer comprising spacer material 2 and removable material 3. If the filling of the removable material 3 in the gaps between the spacer material 2 is done to a constant depth, then this deposition of the second electrode 4 allows the second electrode 4 to have substantially mirroring surface characteristics to the first electrode 1. Further spacer material is deposited on the second electrode 4 as on the first electrode (preferably in the same position as the previous spacers were placed to increase mechanical durability), removable material is introduced between the spacers, the third electrode is deposited, and so on. FIG. 1d depicts the finished converter with the removable material finally removed, and only a space, or preferably a vacuum or inert gas filling remaining in the spaces between the two facing electrodes in the gaps between the spacer material. FIG. 1e shows how a multilayered converter may be built, with each of the second and subsequent electrodes 4 substantially mirroring the surface configuration of the opposite surfaces. Thus the electrodes have related topologies, such that indentations on the inner face of either electrode face protrusions in the facing surface of the other electrode, and where one has indentations the other substantially has protrusions. FIG. 1f shows that removable material 3 in between all the electrode layers is removable at once, at the end.

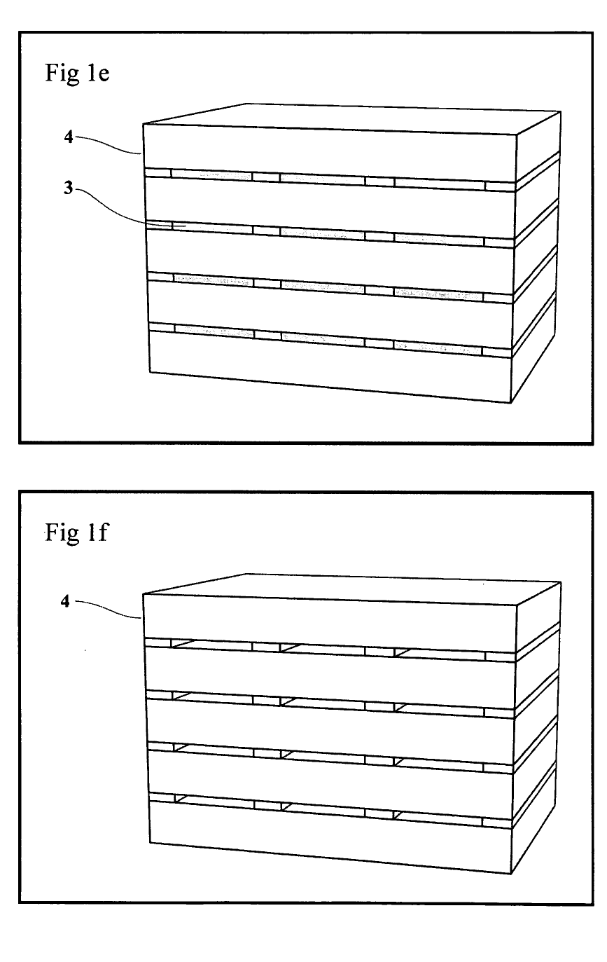

In a second embodiment, a multitude of layers may be built very easily whilst maintaining the positions of subsequent electrodes relative to one another. The present embodiment has the further advantage of using the removable material to shape the spacer, allowing for greater precision in spacer shape, and allowing for adding the spacer as an insulator powder dissolved into a liquid, and other advantages. This approach may be better understood by reference to FIG. 2. A first electrode is prepared, and a mask is placed above it. In FIG. 2a, a soluble or otherwise removable material 3 is applied through the mask, to fill the areas except for the regions that are to be filled with spacer material. The removable material 3, may be applied to a regulated depth, and therefore have an upper surface that is substantially identical to its lower surface. In FIG. 2b, the spacer material 2 is then deposited, or grown in situ into the spaces between the soluble material. In FIG. 2c, a second electrode 4 is deposited above the filled removable material 3. In this way, the lower surface of the second electrode 4 will substantially mirror the upper surface of the first electrode 1. Furthermore, built in this way, the device may be tough enough for subsequent depositions of removable materials 3 and spacers 2 and electrodes 4, enabling the creation of multilayered devices. FIG. 2d illustrates how the removable material 3 may be subsequently removed to leave a vacuum or gas filled region between the electrodes 1 and 4. The removable layer of this embodiment may be grown instead of deposited through a mask, or may be selectively deposited in another way. The device could comprise only two electrodes, or a greater plurality. If more electrodes are required, the above steps are repeated the required number of times. The next step is the removal of the layer or layers of removable materials by the application of appropriate chemicals, or by other means appropriate to the actual embodiment. This leaves the electrodes separated from one another by islands of substantially thermally and electrically insulating spacer material. In another embodiment the removable layer may be removed before the addition of the second electrode, in which case the second electrode would probably comprise a thin film gently laid upon the spacer material. In another embodiment, the removable layer is removed after an electrode has been placed into position above the removable layer, and before the next layer of removable material is applied. It has been described that the insulator spacer material be added or grown up to the height of the soluble material. It is also possible for the insulator material to exceed the height of the soluble material, whereupon an electrode deposited above the soluble material would be somewhat thinner over the insulator material than in other areas. In some cases, this may give the device greater stability, by keeping the spacer locked in position with the upper electrode. In another variation, a suspension of an ultra-powdered insulator, such as silicon oxide, or Al₂O₃, or other material that is substantially thermally and electrically insulating, is deposited across the surface of the bottom electrode. Part of liquid is then evaporated, and the remaining part with grains is frozen, and the next metal layer is deposited. After the desired number of layers has been constructed, the suspending liquid is removed by sublimation or evaporation, and the uniformly distributed powder grains separate the metal layers. This is shown in FIG. 2e. In the present embodiment, the spacer solution is added to fill the hole or holes in the soluble material, after which, the liquid part of the spacer solution is evaporated.

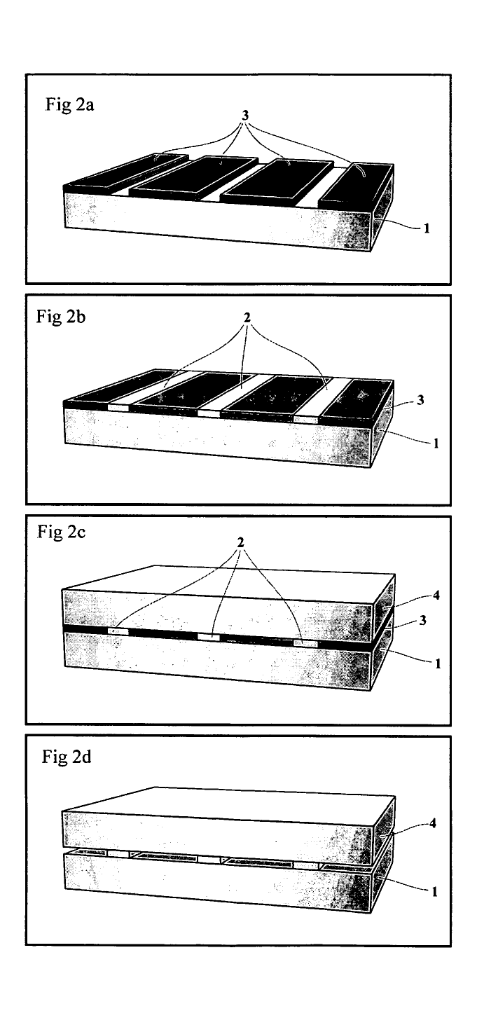

In a third embodiment a multiple of layers, disposed one above the other, and held apart by a sprinkling or arrangement of nanotubes (eg carbon or boron), nanowires or buckyballs placed upon each layer is fabricated. Other similar-sized objects could alternatively be used in this manner, preferably with relatively low thermal and electrical conductivity and high mechanical endurance, to provide separation between respective layers. Electromechanical or similar means may be employed to position the nanotubes or buckyballs etc. Methods for positioning carbon nanotubes and spheres are known in the art, and could be applied to the present invention. In practice, any material of a consistent nano-scale size could be used. Included in variations of this embodiment is also a device made of insulating spacers deposited in pillars on an electrode surface. The next electrode, already prepared, is then laid upon the insulating spacers. One method of making the present embodiment is shown in FIG. 3. FIG. 3a in this example is shown to have lower electrode 1 prepared, and a plurality of carbon nanotubes 5 arranged thereupon. These form the spacer material. A second electrode 4 is shown ready for deposition upon the carbon nanotubes. Although not an implicit part of the invention, FIG. 3a shows how the second electrode 4 is preformed with grooves to hold the carbon nanotubes in position. In an alternative method of preparation, the electrode could be laid with appropriate pressure upon the carbon nanotubes, and be sufficiently pliable, to mold itself partially around the upper surfaces of the carbon nanotubes, and thereby maintain their positions between the electrodes. These examples are provided for illustrative purposes only and should not be seen as limiting the scope of the invention in any way. FIG. 3b depicts a two-layered converter comprising first electrode 1, and second electrode 4, carbon nanotubes 5 positioned there between and spaces for a vacuum or gas backfill provided. FIG. 3c shows a multilayered version of the same device.

In a fourth embodiment, vertical nanotubes and nanorods (nanowires) may be used as spacers (FIG. 3d). Methods for growing an array of arranged nanotubes vertically are known to the art. For example, but without limitation, catalysts may be deposited in an appropriate arrangement through a mask. Thus a catalyst can be deposited on the first electrode, then short (2-10 nm) nanotubes grown on the surface first electrode. A removable substance is now deposited on the surface around the nanotubes up to their ends, and, if the removable material is a liquid, frozen. A metal layer is deposited above, and the removable materials removed. The procedure is repeated until the device has a required number of layers. The advantage of such an approach to spacer preparation is its practically atomic structure of course, it is important that the nanotubes (nanorods) have sufficiently low electrical conductivity. This method can also be used for growing of “common” regular spacer array at the electrode surface. Deposition of the catalyst and subsequent spacers growth (by molecular epitaxy, from gas phase, or another way) is easier, in comparison with direct spacer formation. Moreover, instead of a catalyst molecule, a growth point can be formed by electron beam influence upon a specially prepared electrode surface. This approach is used for forming a regular array of quantum points on a semiconductor surface, and is readily adapted to the present application.

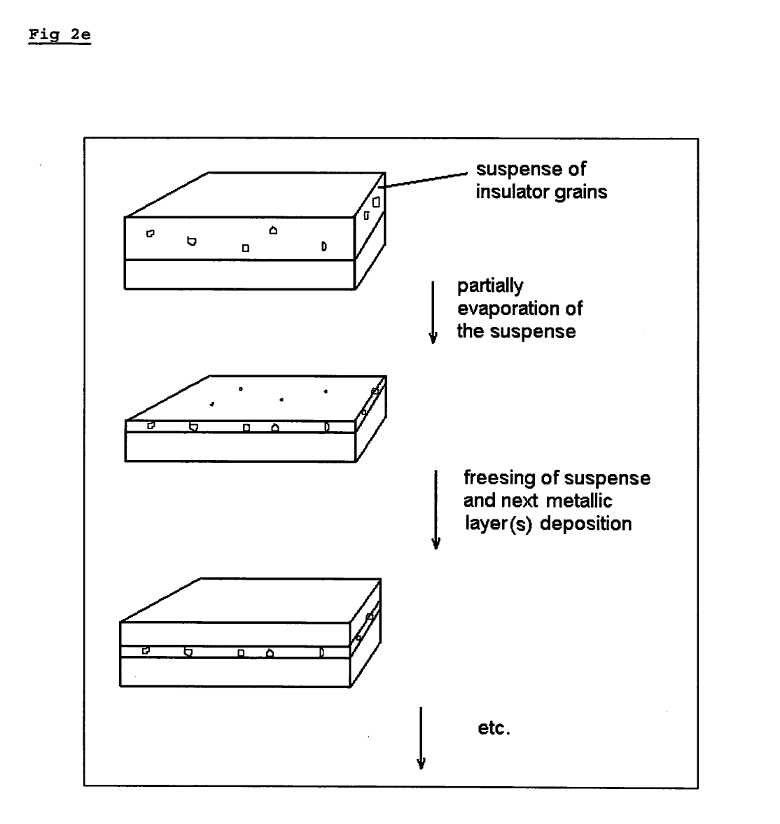

In a fifth embodiment, the electrodes may be spaced apart very precisely. The process is shown in FIG. 4. Explicit methods and materials are given for illustrative purposes, and to provide one best mode embodiment, however, variations on the theme should certainly be considered as within the scope of the present invention. In FIG. 4a, a silicon substrate 6 is prepared as the first electrode 1. A mask with at least one hole in, for example in its center, or with many holes around the periphery, is positioned above the silicon substrate 6, and aluminum 7 is deposited through the hole or holes, to form a very low column. In FIG. 4b, silver 8 is deposited over the silicon substrate 6, and copper 9 is grown upon it, together forming a subsequent electrode 4. This forms a sandwich, which is opened, under suitable conditions, i.e. copper plate is separated from silver layer. Positioning means 10 may optionally be added to the device, for separating and subsequent positioning of electrodes. FIG. 4c shows the separated sandwich, and pure oxygen 11 is then let in to the opened sandwich. The aluminum column 7 will oxidize to form mainly Al₂O₃. The volume of Al₂O₃ is approximately 2.5 times more than of two aluminum atoms. Therefore, the original aluminum column 7 will grow upwards approximately 2.5×50 Å=125 Å. (50 Å is proposed as the original depth of the aluminum column, because aluminum oxidizes to that depth and then saturates, so 125 Å is seen as the maximum possible growing up of Al). The next stage, shown in FIG. 4d, is to bring the upper electrode back so that it touches the Al₂O₃ and that will limit spacing between electrodes. Alternatively, as in FIG. 2e, the electrodes can be positioned at the correct distance for thermotunneling immediately after separation and the aluminum spacer can be grown to meet the second electrode, without the need for subsequent electrode positioning. Al₂O₃ is a good insulator, having low thermal and electrical conductivity. In the event that the area of the aluminum is substantially small relative to the electrode area, the thermal and electrical conductivity introduced by the aluminum will be negligible. This method allows one to control the spacing between electrodes because one can regulate the depth of the aluminum oxide by regulating the time that oxygen is applied and the temperature. For example, if one makes the aluminum oxidize up to a depth of 20 Å, the result will be an approximately 50 Å lift up. Since aluminum oxidizes much faster than silicon (at least a hundred times faster), there should be no problem of silicon oxidization during the time the aluminum takes to oxidize. Further aluminum islands could be grown also on the peripheries of the electrodes if a mask with more holes is applied. In the present example, instead of a mask to selectively deposit the aluminum, a shaping material could be selectively deposited (through a mask, for example) onto a first substrate. The Al could then be added to fill gaps therein, and subsequently be grown. The shaping material could be subsequently removed, or it could even be made of suitable material to form the lower electrode. One benefit of the shaping material remaining in place is that growth of oxidized aluminum is forced to be upwards (at least for the part of the aluminum which remains below the level of the shaping material), which allows greater precision of electrode spacing, than if the aluminum could have oxidized sideways. The present embodiment allows the opposite surfaces of electrodes to remain matching one another, vis-a-vis their position, and even their surface structure, which are important considerations. This is because they originally comprised one sandwich. Methods to separate the electrodes and subsequently to draw them nearer can involve mechanical screws or piezo techniques, as well as other techniques known in the art. The present embodiment is not limited to the materials described, which were provided solely for ease of understanding. For example, Al₂O₃ was described as having been grown in situ, however, it could be replaced with other materials that can be grown in situ. Furthermore, the present embodiment using matching electrodes can be used in conjunction with other methods described explicitly or by reference in the present application, for example the matching, separated electrodes can be spaced apart by adding a nano-material, or using a dried out liquid, etc. Such matching electrode faces can be used with a great variety of intermediate layers used to form the spacer.

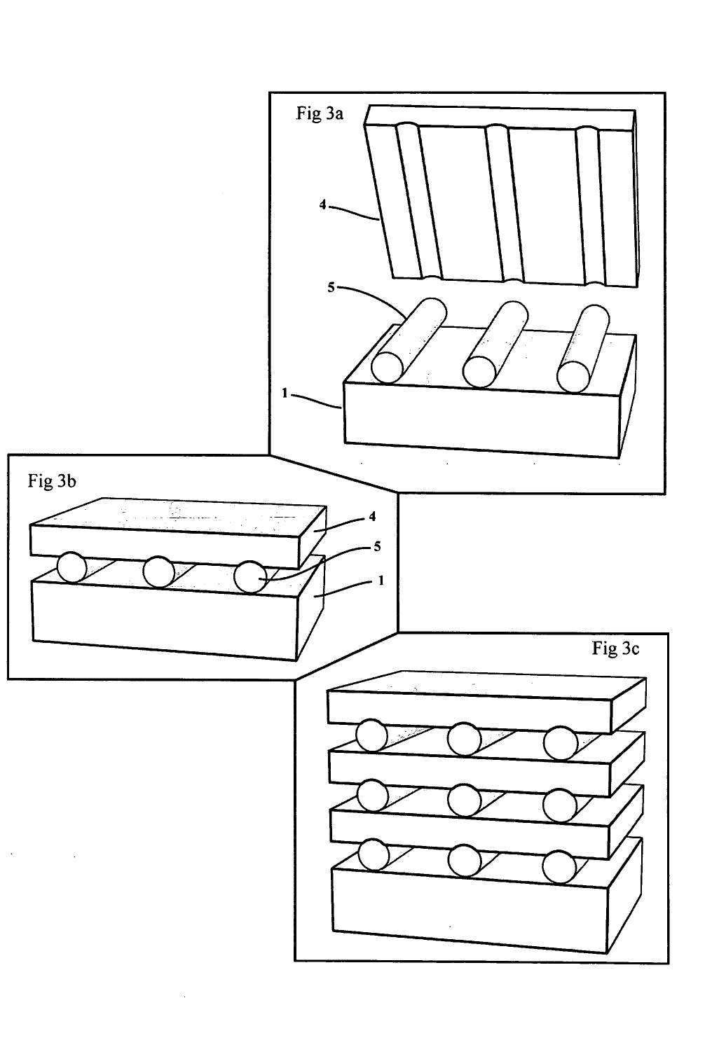

As disclosed above, the present invention is directed to a thermotunneling converter having two electrodes, separated from one another by a spacer material. In a particularly preferred embodiment, shown in FIG. 5, a surface of the first electrode is as smooth and flat as is technologically possible. The second electrode is formed on top of the removable layer, deposited so as to follow the contours of the underlying first electrode as closely as possible, as shown in FIG. 5a. Alternatively, the removable layer is deposited so that it ‘fills in’ gaps in the surface of the first electrode, as shown in FIG. 5c. This means that the surface of the second electrode is a replica of the surface of the first one at the nanoscale (atomic scale), and that the approach disclosed herein is possible not only for relatively big gaps d>>δ (see FIG. 5b), where δ is the deviation of the electrode surface from the flatness, but for small gaps also. This overcomes problems associated with non-matching electrodes, as shown in FIG. 5d, where there are regions where the electrodes are widely separated and regions where there is contact between them.

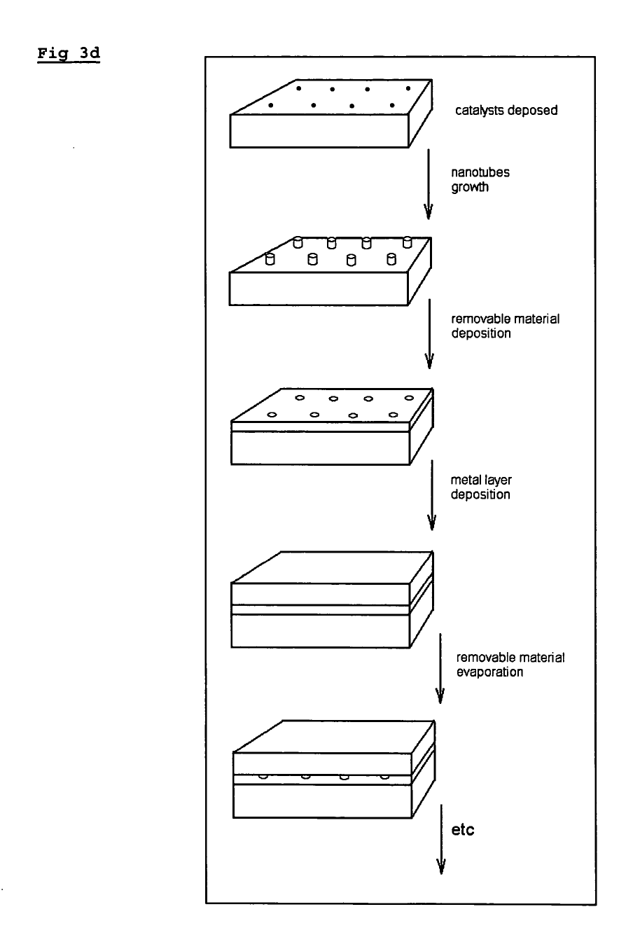

Using spacers in this way reduces the thermal conductivity of the device more than using a layer of insulating material across the whole of the gap, as described by Huffman, by 1/ns times, where s is the cross section of the one spacer, n is the number of spacers per unit area, and the term ns thus represents the proportion of the surface area of the electrode covered by the spacer. The lower limit of s is determined by a mechanical load on the spacers due to atmosphere pressure and Coulomb attractions between the electrodes, which have electrical charge of opposite sign. This load must be less than breaking point of spacer material K:
(P+F)/ns<ℑK, (1)
and ns>(P+F)/ℑK (1a)

where P is atmospheric pressure, K is the breaking point of the spacer material, ℑ is the margin of safety, and F is the attractive force which approximates to V²/4πd², where V is the applied or generated voltage, and d is the interelectrode gap. The sum of P+F appears because forces applied to all inner layers are balanced, except the first and last ones, which are connected with envelope as shown in FIG. 6b. So, forces F˜V²/4πd² act on the envelope in the same way as the atmospheric pressure. Uncompensated forces remain on the first and last electrodes only. As a result, attractive forces act in addition to atmosphere pressure. For low values of d (˜nm) Coulomb forces are great. Thus, for V=1V, values for F are 0.9 kg.cm⁻² for d=10 nm, 3.6 kg.cm⁻² for d=5 nm, and 10 kg.cm⁻² for d=3 nm.

For the strongest insulator materials such as Al₂O₃, ZrO₂, SiO₂ (quartz) K is in the region of 200-300 kG/mm². For example, for Al₂O₃, which is one of the preferred materials for spacers, K=230-270 Kg/mm² for temperature range 0-100° C. For mean value K=250 kG/mm², ℑ=2 and typical gap of tunnel converter d=5 nm, for applied voltage V=1V ns≦˜4*10⁻⁴. Coulomb forces are proportional V², so ns decreases rapidly with decreasing V. So, for V=0.6V ns≦˜2*10⁻⁴. For V<0.1V Coulomb forces are negligible in compare with atmosphere pressure for all gaps, and for this limit case ns≦1*10⁻⁴. This corresponds to power generated by tunnel diodes, when the output voltage is in the range ˜1-10 mV. Coulomb forces are also inversely proportional to d², so for low values of d (less than about 5 nm), the amount of spacer material between layers would increase rapidly. But for low d the applied voltage, V, decreases in general case, and it compensates, at least partially, for the increase of in force between the layers. So, each gap of this embodiment can be ˜10,000 times more effective in comparison with Huffman's device with an insulator layer across the all of the electrode.

Due to this minimization of insulating material between conductive layers, the number of conductive layers N may be in the region of 100 layers (as opposed to 1,000,000 as has been previously suggested by Huffman), or even just ten or even fewer. Furthermore, it is possible to build a thermotunneling device having only two electrodes, spaced further apart than the 40 angstroms delineated by Huffman. The number of electrodes N can be determined from (1) and the thermal conductivity of the spacer K, which determines a back heat flux, Q, (from collector to emitter of cool device) per unit area of electrode surface. Q=δT*κ*ns/d, where δT=ΔT/N−temperature difference between adjacent electrodes.

If the permissible reduction of device efficiency due to spacer thermal conductivity is Dₛ, then
Q≦DₛW, (2)

and
(ΔT/N)*κ*ns/d≦DₛW, (2a)

So,
N≦ΔT*κ*ns/d*Dₛ (3)

For SiO₂ and ZrO₂ the thermal conductivity is ˜0.015 J/cm*sec*deg and ˜0.2 J/cm*sec*deg for Al₂O₃. Assuming that the cooling power, W is ˜10W/cm⁻², Dₛ is 0.5, ns=10⁻⁴, and ΔT=50K, then for SiO₂ or ZrO₂ N is 30 and for Al₂O₃, N is 400.

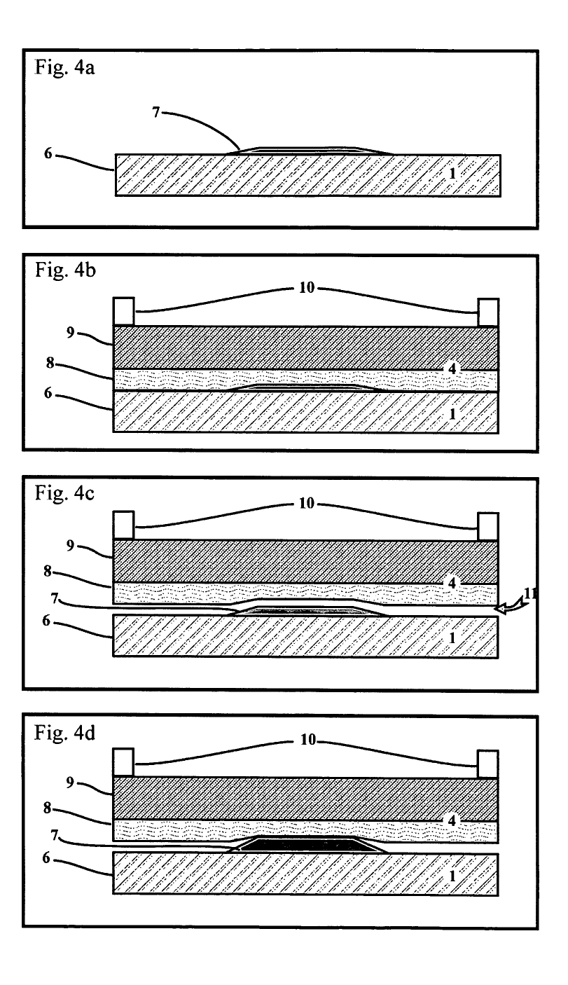

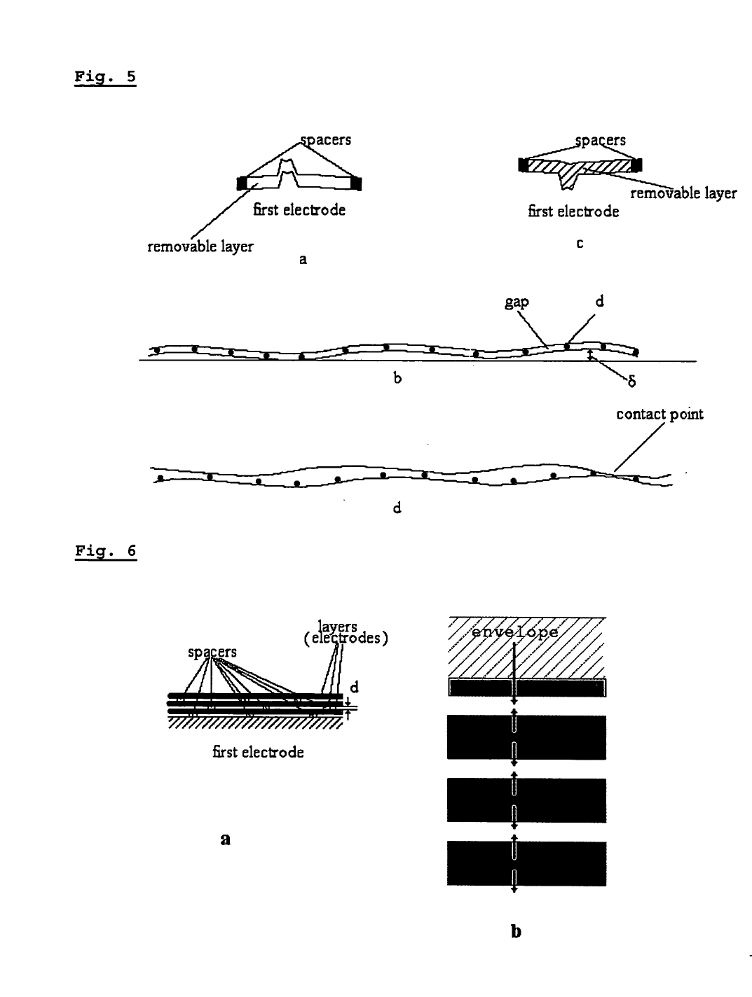

In a sixth embodiment, shown in FIGS. 7 and 8, the electrodes may be thick (H>>d) and the spacers may be long (their longitudinal dimension Λ>>d) and placed in deep pits. The first step in this embodiment is the production of an array of deep pits with depth h>>d (for example, by ion bombardment etching in gas discharge plasma). The second step is the deposition at the bottom of the pit a means (catalyst, for example) for growth of the insulator spacer (FIG. 7), or nanotube, or nanowire (FIG. 8). Then the spacer is grown upwards to exceed the electrode surface level by a distance d:
Λ−H=d (13)

A removable material is deposited to fill the space between pit walls and spacer as shown, and its upper level is level with the top of the spacers. Subsequently the next electrode material is deposited, the pits are etched, etc. An advantage of this embodiment is that this arrangement of layers permits a decrease in the thermal conductivity of the spacers by a factor of h/d. Correspondingly, the layer number decreases by the factor h/d. this approach is particularly important for devices that would otherwise have a large number of layers (big V, small d, relatively big κ). Reduction in the number of layers also reduces the time required to produce each device, and reduces manufacturing costs, etc. This method is the most convenient for producing simple two-electrode devices. If h/d=2-3 only, even in this case it give a significant advantage.

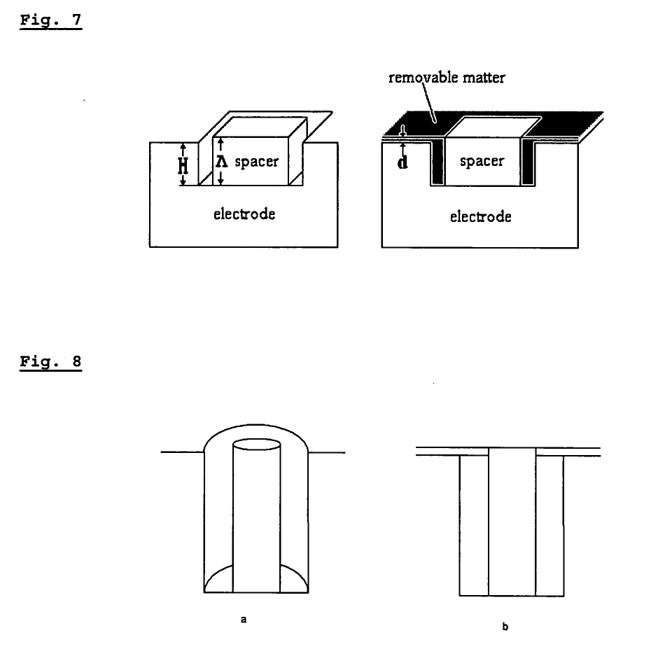

The second and subsequent electrodes (excepting the last one) can have in general case an identical complicated structure (FIG. 9). If the first electrode 1 is an emitter, then it is preferable to deposit a layer 4 above the spacer material 2 and removable material 3 of material that is optimum for collector function. A lower limit of the thickness of this layer can be from ˜1 nm (some atom layers) up to ˜100-200 nm. After this first layer can be deposited a layer 5 of a material optimum as emitter (FIG. 9a)

First and last electrodes should be prepared from materials that allow sealing or gluing to the envelope or housing, or at least such material should cover their sides. At the same time these electrodes should have a sufficiently high thickness (˜0.1 mm or more) for sealing or gluing to envelope without deformation.

Alternatively, when the thickness of these layers is insufficient for the mechanical durability of the electrode, a third layer 6 of firm metal with high modulus of elastically E₁ can be deposited between these layers (FIG. 9b). The need for mechanical durability arises because the attractive forces between inner electrodes is not exactly zero due some deviation of the gap size from the mean value d and some asymmetry gaps above and below the electrode. Assuming that the gap accuracy ˜5%, the difference in forces is ˜10% of value F=V²/4πd², i.e. tenths of atmosphere for d˜5 nm and V˜1V. So, layers cannot be too thin, they should resist to bending and destroying under the residual attractive forces, which can be significant. In addition the spacers need to be arranged in a regular fashion and sufficiently close to one another to prevent large deformation of the layers.

From relation (1) and this condition we can determine number of spacers n and corresponding value of electrode (layer) thickness H (see FIG. 3a). It is evident, the more spacers, the less H. But the spacer cannot be made too thin—its minimum transverse dimension should be near d. So, in (2) s≈d, and
n≦(P+V²/4πd²)/ℑKd², (4)

and the mean distance between spacers L
L=1/n^{1/2} (5)

Alternatively, if δ is a maximum deviation of the gap size from mean value d, Δ—highest possible bending of the layer, then F*2δ/d=(2δ/d)V²/4πd² is the maximum force, which affects on the layer. It is known that the maximum deformation of a plate of thickness H from material having a modulus of elasticity E₁, which is supported on a square array of bearings with distance L between them, is at the centre of the square, and the approximate expression is
Δ=( 1/16)*(F*2δ/dE₁)*(4L⁴/H³) (6)
H³=L⁴*V²*δ/8πE₁Δd³ (7)

For the example above ns=10⁻⁴ and d=5 nm, s=5 nm×5 nm=25 nm², n=4*10⁸ and L=500 nm. Assume E₁=20,000 kG/mm² (refractory metals) and Δ=d/10=0.5 nm, then this gives a value for H of 100 nm. It is reliable layer thickness, which may be deposited by many ways. If depositing spacers in a square formation is more convenient, it needs to have bigger L and should use thicker H. For s=250 nm² L≈1500 nm, and H=450 nm. Correspondingly, for s=50 nm×50 nm=2500 nm² L=5000 nm=5μ, H=1000 nm=1μ. In all cases numbers remain reliable. The essence is that the fewer the number of spacers, the simpler the technology, and the spacers with the largest sizes most favorable.

For the low voltage region V<˜0.1V, Coulomb forces are low even at small d, and limitations on the distance between spacers and on the thickness of the layer due these forces are replaced by demands for mechanical durability against sounds, vibrations, shocks, etc.

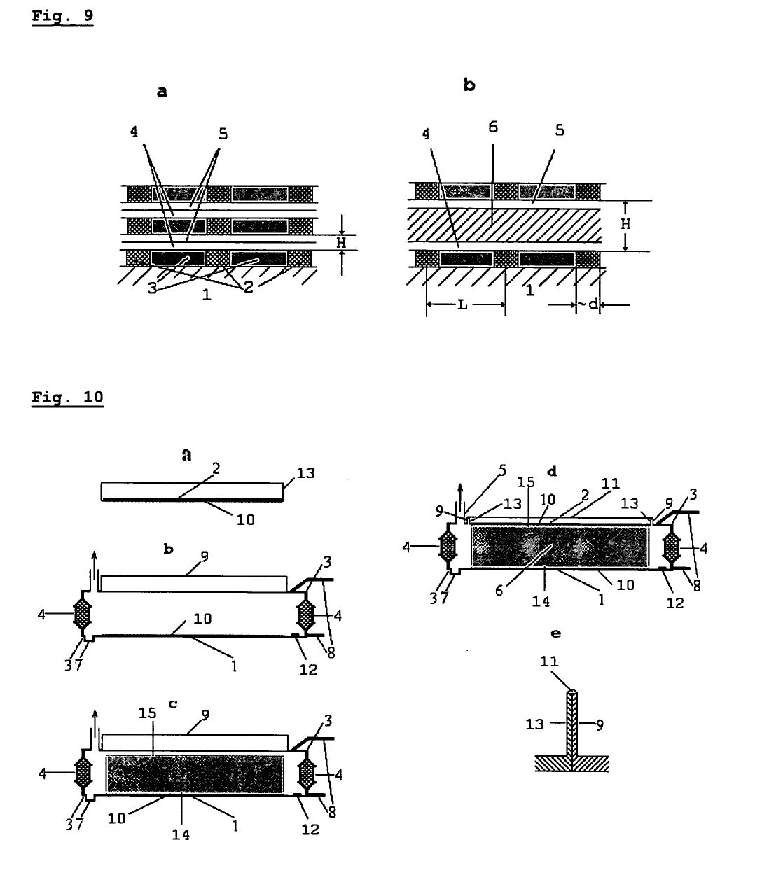

After the electrode package has been prepared it should be encapsulated into an envelope. One possible method of encapsulation is illustrated in FIG. 10. In this method the envelope consist from two parts—a collector (a) and an emitter (b). Emitter part consists of a plate onto which the first electrode is mounted (1), body of the envelope (3) with insulator insertion (4) and foil shoulder (9) for joining with collector part. The outer side of the plate (1) is also intended for mounting on the cooled object (for cooling devices) or the heat reservoir (for power producing devices), and should not have lugs. The plate (2) should, as a rule, be cooled during operation—for cool device by air convection or by airflow. The envelope body has a tube (5) to allow the removal of removable matter, evacuation, introduction of an inert gas and active material (Cs, Ba, etc.). It also has a reservoir (7) for activation (work function decreasing) of the electrode surfaces, and a getter (12) for residual gas absorption. The collector part is a plate for mounting the last electrode (2) having a foil shoulder (13), which can be inserted with minimum clearance into the shoulder on the emitter part. For the encapsulation of both plates for electrode mounting, (1) and (2) are covered by a layer of low temperature solder or special metal paste such as amalgam (10). Then the electrode package is laid on the solder into the emitter part of the envelope and first electrode (14) sealed to it by heating the envelope, or another means (FIG. 10c). Then the collector part is laid on the last electrode (15), and its shoulder enters in the emitter part shoulder (FIG. 10d). The last electrode is sealed to collector part of the envelope, and both shoulders are welded by electron or laser beam, producing the weld junction (11).

Sealing of the first and last electrodes should ensure not only mechanical durability, but good thermal and electrical contact. For high efficiency operation at heat flows of ˜10W/cm², the temperature difference on the seal should not exceed some percents of the total temperature difference ΔT on the device. So, for cool devices with typical ΔT˜50K it is ˜1-2K. The electrical resistance of the contacts is especially important for power producing devices, because in this case an output voltage in general is low, ˜0.01V. So, voltage drop at the contacts jR (j—operation current, R—contact resistance of 1 cm² square) should be less than some percents of jR for high device efficiency. For currents j˜10-100 A/cm² it corresponds R<˜10⁻⁵-10⁻⁶ohm/cm². For cool device most important is low resistance of the emitter, because in this case a heat j²R is evolved at the contact and directly decrease the emitter cooling. For operation currents j˜10-100 A/cm² and cooling ˜10 W/cm² we should have R<˜0.01-0.001 ohm/cm², if we want to decrease cooling not more than some percents.

The envelope is an additional path for heat leakage from hot electrode to cold one. It puts an additional demand on the envelope insulator heat resistance. For a reduction in device efficiency due to envelope heat leakage to be less than Dₑ, a back heat flux Qₑ should be less than Dₑ*W, where W is a full cool power:
Qₑ=ΔT*S*κₑ/1≦˜Dₑ*W, (8)

where S is a full cross section of the envelope insulator, Kₑ—its thermal conductivity, 1—its length. If we have device with electrode dimension 1 cm×1 cm and specific cooling power 10 W/cm², W=10W/sec. If insulator has thickness 0.5 mm, for this case S=4×10×0.5 mm²=0.2 cm². For κ=0.015 J/cm*sec*deg, ΔT=50K and Dₑ=0.1 l=1.5 mm. For Dₑ=0.01 and the same condition 1=15 mm.

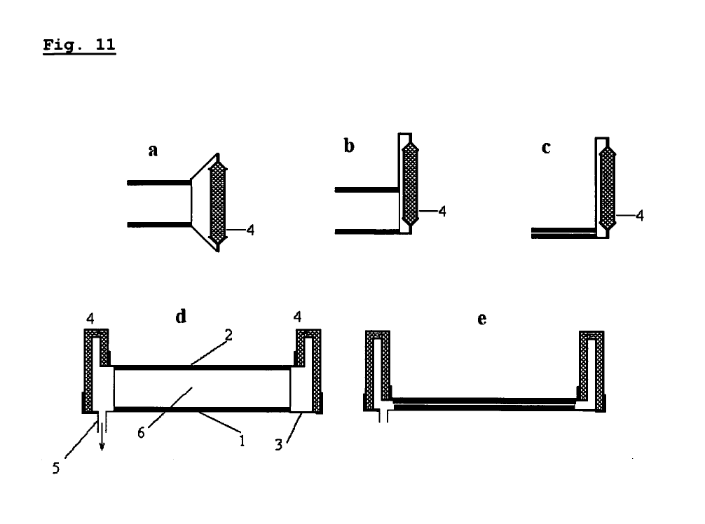

If a longer insulator is required, an alternative approach for constructing the insulator unit can be used, as is shown in FIG. 11. The cases a-c at this figure corresponds to long cylinder insulator 4, cases d-e corresponds to double cylinder. Encapsulation in such cases is as in FIG. 10. The envelope consists of two parts—collector and emitter parts, as before. For encapsulation, both plates for electrode mounting 1 and 2 are covered, as in the case FIG. 10, by a layer of low temperature solder or glued metal. Then electrode package 6 is laid on the solder into the emitter part of envelope 3 and the first electrode is sealed to it by heating of the envelope, or another means. Then the collector part is laid on the last electrode, and its shoulder enters in the emitter part shoulder (for the sake of simplicity shoulders are not shown in FIG. 11d). The last electrode is sealed to collector part of the envelope, and both shoulders are welded by electron or laser beam, to produce the weld junction. As an emitter shoulders can be used insulator itself, FIG. 11d corresponds to this case namely. The activated materials (Cs and so on) and getter introduced the same manner, out-gassing and pumping is fulfilled through tube S. FIG. 11e shows the case, when insulator length is much more the electrode package thickness.

In the limit case, when the envelope eliminates all compressed forces acting, spacers are loaded by uncompensated Coulomb forces F*2δ/d=(2δ/d)V²/4πd² only. But even for large applied voltages these forces are not great. For example, for V=1V and d=5 nm F*2δ/d=0.36 kG/cm² (for δ/d=0.05). This is 3 times less than atmosphere pressure, and, correspondingly, the number of layers can be 3 times less. For low V<0.1V force is 100 times less, and it is possible to for the device to have two electrode only.

In general intermediate case, when the envelope compensates the compressed forces partially only, α part of the compressed force (P+F) is applied to the electrode assemblage, and (1−α) to envelope insulator, we can write:
α(P+(2δ/d)V²/4πd²)/ns=ℑₛKₛ (9)
(1−α) (P+(2δ/d)V²/4πd²)/S=ℑₑKₑₙᵥ, (10)

where ℑₑ is the margin of safety for envelope insulator. Then
s=α(P+(2δ/d)V²/4πd²)/nℑKₛ (11)
S=(1−α) (P+(2δ/d)V²/4πd²)/ℑKₑₙᵥ (12)

### EXAMPLE 1

Explicit details of how to make a sample device are as follows. This example is given for purely illustrative reasons and should not be considered as limiting the scope of the invention in any way. A polished metal plate is covered by a thin (about 100-1,000 Å) film of gold, or other metal that does not grow a native oxide layer. Onto this film, a layer of aluminum oxide or other insulator of approximately 50 Å thickness is deposited in an array. After this an appropriate fluid substance (which does not react with the metal film), is added, to fill the depressions between the insulator array, and hardened. After freezing, a second thin gold film as described above is deposited, upon which a thicker film of a cheaper metal, such as Al, Fe, Ni, etc is deposited, for mechanical solidity. The liquid is then pumped out (or otherwise released) and the process can be repeated again and again. Each intermediate conducting layer comprises a triple layer of gold-cheap metal-gold. The last metal film must be relatively thick, as it is to form the final electrode, and to it, a thicker metal plate must be attached (by soldering, for example). This plate, as the base one, prevents defects due to atmosphere pressure, and they serve as the main electrodes, having current leads attached to them. Besides for this, both upper and lower plates may encapsulate the device using an insulator hermetic (glue or other special compound etc.) around the perimeter. Of course, a cross section of this insulator should be minimal and total length maximum in order to decrease the heat losses due to thermal conductivity. The advantages of such a device are numerous. First of all the temperature difference between electrodes is divided by the number of layers (˜100). Thus for each layer the delta-T is small—a very few degrees. So, the longitudinal size difference between metal layers due to different thermal expansion of layers will be very small—less than the distance between each adjacent electrode element. Such a low size differences can be compensated by relatively small mechanical tensions in metal layers, and the assembly in total will behave as a monolithic sample. Such a device will be insensitive to temperature gradients. Also, as a monolithic device, having an insulator blocking between metal layers, the device will be practically insensitive to sounds, vibrations and poundings. Also, the device is not complicated, as can be seen. It is a chip indeed: a rectangular metal plate ˜1 by 1 cm and ˜1-2 mm thick with a thin insulator rim and with electrical leads at each side, which does not need any preparation for working, nor any special requirements for storage. An additional advantage is that metals, which do not grow a native oxide, such as gold, will provide greater efficiency, since oxides allow for greater undesirable heat carrying by residual air or inert gas circulation. This advantage is specifically so at maximum pressures.

Whilst the present embodiment has been described with 100 or so layers, it is envisioned that it will be possible to build a useful device using 10 or even fewer layers, or even just two layers, using appropriate materials and sizing of the electrodes, intermediate elements and spacers. The present example allows for the electrodes to not have to be separated and then carefully positioned, respective to one another, since the respective layers can simply be laid upon the spacer material, which provides for appropriate spacing between layers.

The present invention has been described with regard to six basic embodiments. Each embodiment brings out new facets of the invention, but many details are interchangeable. Furthermore, many details have been specifically given, for ease of understanding, which are not to be considered limiting to the present invention. A few examples of such follow:

Each electrode is not necessarily composed of only a single layer. For example, electrodes could be composed of a thin layer of silver upon which Cu is subsequently grown. Logistics of which conductors and which insulators will be used will depend on the needs of the particular device.

Another way to form the solution mentioned above is to use globular polymer molecules suspended in solution. These have very low thermal and electrical conductivity.

One particular material that is suggested as particularly suitable is silicon macromolecules (polysiloxanes), because some of these are stable up to 800K and even higher.

Another way to apply the present invention is to grow the insulator layer directly onto the electrode surface. The electrode surface would first be covered entirely by a protective layer, which is removed in places by etching, or ion or electron beam, etc. Then an insulator may be grown in the exposed places.

The various embodiments can be made with a large variety of materials. In most cases it may be desired to obtain a low work function (WF). Such obtaining may be achieved in a variety of ways, the below descriptions should be considered exemplary only.

Alkali or alkali earth vapor at low pressure (with and without oxygen) may be added to a device as described above before it is sealed. Alternatively, materials from the lanthanum group elements and their compounds, especially their oxides. Yttrium and scandium oxides have relatively low WF. Most convenient possibility is cesium, especially when used in conjunction with gold, platinum, etc., when they produce an intermetallic compounds with a low (˜1.4-1.5 eV and less) WF, or when the electrodes are treated by oxygen before or after Cs introduce. The minimum known WF value ˜1 eV is observed namely for the CsO compounds. A practical way to implement this includes using a device having electrodes coated with gold or another appropriate material, evacuating and filling the device with cesium vapor at low pressure for some time, and then sealing it.

Thus, it is apparent that there has been provided, in accordance with the present invention, a method and apparatus for a thermotunneling converter that satisfies the advantages set forth above. The thermotunneling converter may be used to convert heat to electrical power, and vice versa and may be used in a great variety of applications. Furthermore, the device may even be used in cooling applications, in which an external electrical potential is applied to cause heat to flow from the cold side of the converter to the hot side.

While this invention has been described with reference to numerous embodiments, it is to be understood that this description is not intended to be construed in a limiting sense. Various modifications and combinations of the illustrative embodiments will be apparent to persons skilled in the art upon reference to this description. It is to be further understood, therefore, that numerous changes in the details of the embodiments of the present invention and additional embodiments of the present invention will be apparent to, and may be made by, persons of ordinary skill in the art having reference to this description. It is contemplated that all such changes and additional embodiments are within the spirit and true scope of the invention as claimed below.

1. A thermotunneling converter comprising:
a) a plurality of electrodes having surfaces substantially facing one another;
b) a respective spacer or plurality of spacers disposed between and in contact with said electrodes to form gaps between said electrodes, where said gaps are less than the surface roughness of the material, and where the proportion of a surface area of said plurality of electrodes covered by said spacers<1.

2. The thermotunneling converter of claim 1 wherein said proportion of a surface area of said plurality of electrodes covered by said spacers>(P+F)/ℑK, where P is atmospheric pressure, K is a breaking point of said spacer, ℑ is a margin of safety, and F is an attractive force between said electrodes.

3. The thermotunneling converter of claim 1 wherein said proportion of a surface area of said plurality of electrodes covered by said spacers is approximately a quarter.

4. The thermotunneling converter of claim 1 wherein said gaps are in the range of 3-15 nm.

5. The thermotunneling converter of claim 1 wherein said spacer or spacers comprise material selected from the group consisting of SiO₂, ZrO₂, and Al₂O₃.

6. The thermotunneling converter of claim 1 wherein said spacer or spacers comprise material that is a thermal insulator.

7. The thermotunneling converter of claim 1 wherein said spacer or spacers comprise material that is an electrical insulator.

8. The thermotunneling converter of claim 1 wherein the gaps are evacuated.

9. The thermotunneling converter of claim 1 wherein the gaps are filled with an inert gas.

10. The thermotunnel converter of claim 1 wherein said plurality of electrodes≧ΔT*κ*ns/d*Dₛ.

11. The thermotunneling converter of claim 1 wherein said plurality of electrodes is 400 or fewer.

12. The thermotunneling converter of claim 1 wherein said plurality of electrodes is 100 or fewer.

13. The thermotunneling converter of claim 1 wherein said plurality of electrodes is 30 or fewer.

14. The thermotunneling converter of claim 1 wherein said spacer or plurality of spacers comprises a plurality of nanotubes, nanowires or buckyballs.

15. The thermotunneling converter of claim 14 wherein one of the electrodes is a thin sheet of metal having surface indentations of appropriate sizing for maintaining the positions of said nanotubes, nanowires or buckyballs.

16. The thermotunneling converter of claim 1 wherein the portions of said surfaces substantially facing one another that do not have a spacer between them are characterized in that: indentations on the inner surface of either electrode face protrusions in the facing surface of the other electrode.

17. The thermotunneling converter of claim 1 wherein one or more of said plurality of electrodes comprises a silicon substrate.

18. The thermotunneling converter of claim 1 wherein one or more of said plurality of electrodes comprises a thin layer of silver and a thicker layer of copper.

19. The thermotunneling converter of claim 1 wherein said spacer or plurality of spacers have the form selected from the group consisting of: hexagonal arrays, strips, circles, rings, lattices, pillars, and bottom heavy pillars.
